(19) United States
(12) Patent Application Publication
(10) Pub. No.: US 2014/0042875 A1
(43) Pub. Date: Feb. 13, 2014

(54) PIEZOELECTRIC ELEMENT, PIEZOELECTRIC DEVICE AND METHOD OF MANUFACTURING PIEZOELECTRIC ELEMENT

(71) Applicants: Kazufumi SUENAGA, Tsuchiura (JP); Kenji SHIBATA, Tsukuba (JP); Kazutoshi WATANABE, Tsuchiura (JP); Akira NOMOTO, Kasumigaura (JP); Fumimasa HORIKIRI, Nagareyama (JP)

(72) Inventors: Kazufumi SUENAGA, Tsuchiura (JP); Kenji SHIBATA, Tsukuba (JP); Kazutoshi WATANABE, Tsuchiura (JP); Akira NOMOTO, Kasumigaura (JP); Fumimasa HORIKIRI, Nagareyama (JP)

(73) Assignee: Hitachi Metals, Ltd., Tokyo (JP)

(21) Appl. No.: 13/960,460

(22) Filed: Aug. 6, 2013

(30) Foreign Application Priority Data
Aug. 7, 2012 (JP) 2012-174837

(51) Int. Cl. H01L 41/18; H01L 41/22

(52) U.S. Cl. CPC H01L 41/18; H01L 41/22
USPC 310/365; 29/25.35

(57) ABSTRACT

A piezoelectric element includes a substrate, and a lower electrode layer, a piezoelectric film represented by a general formula of (NaₓK_{y}Li_{z})NbO₃ (0<x≦1, 0<y≦1, 0≦x≦0.2, x+y+z=1) and an upper electrode layer formed on the substrate. The piezoelectric film has a crystal structure of pseudo-cubic crystal, tetragonal crystal, orthorhombic crystal, monoclinic crystal or rhombohedral crystal, or has a state that at least two of the crystal structures coexist. A difference between the maximum value and the minimum value of an energy of Na-K absorption edge measured by an electron energy loss spectroscopy or an X-ray-absorption fine-structure spectroscopy in a direction of the film thickness of the piezoelectric film is not more than 0.8 eV.

The present application is based on Japanese patent application No. 2012-174837 filed on Aug. 7, 2012, the entire contents of which are incorporated herein by reference.

### BACKGROUND OF THE INVENTION

1. Field of the Invention

This invention relates to a piezoelectric element configured such that a piezoelectric property is improved by accurately controlling the atomic-level structure of a lead-free piezoelectric film using lithium potassium sodium niobate, a piezoelectric device and a method of manufacturing a piezoelectric element. 2. Description of the Related Art

A piezoelectric element is processed so as to form various piezoelectric devices in accordance with a variety of the intended uses, in particular, is widely used as a functional electronic component such as an actuator that allows an object to be changed in shape when an electric voltage is applied thereto, a sensor that generates an electric voltage due to the change in shape of the element reversely.

As the piezoelectric element that is used for the application of the actuator and the sensor, a lead-based dielectric material that has an excellent piezoelectric property, in particular, a Pb(Zr₁₋ₓTiₓ)O₃ based perovskite type dielectric material that is referred to as a PZT has been widely used, normally the PZT dielectric material is formed by sintering an oxide comprised of an individual element.

In addition, recently, in terms of environmental consideration, it is desired that a piezoelectric material that is lead-free is developed, and it is in progress to develop lithium potassium sodium niobate represented by a general formula of (NaₓK_{y}Li_{z})NbO₃ (0<x<1, 0<y<1, 0<z<1, x+y+z=1) or the like. The lithium potassium sodium niobate has a piezoelectric property comparable to the PZT, thus the niobate is expected as a strong candidate of a lead-free piezoelectric material.

On the other hand, at present, various electronic components become more downsized and upgraded, thus it is strongly needed for the piezoelectric element to be downsized and upgraded. However, a piezoelectric film of piezoelectric element manufactured by a conventional manufacturing method such as a sintering method, particularly if it has a thickness of not more than 10 μm, is configured to have a thickness that is close to the size of the crystal grain constituting the element, thus the influence thereof cannot be ignored. Consequently, a problem is caused that variation and deterioration in the property become prominent, thus in recent years, for the purpose of preventing the problem, a forming method of a piezoelectric film in which a thin film technology and the like are applied instead of the sintering method has been investigated.

Recently, a PZT thin film formed by a RF sputtering method is put into practical use as an actuator for a head of a high-definition and high-speed ink-jet printer, a downsized and low-cost gyro sensor or angle sensor (for example, refer to JP-A-H10-286953 and “High performance piezoelectric material and advancing applied technology” supervising editor: Kiyoshi Nakamura, published by Science & Technology, 2007).

In addition, a piezoelectric element that has a piezoelectric layer of lithium potassium sodium niobate that is lead-free is also proposed (for example, refer to JP-A-2007-019302).

### SUMMARY OF THE INVENTION

A piezoelectric element having a piezoelectric layer comprised of a lead-free material is fabricated, thereby a printer head of a high-definition and high-speed ink-jet printer and a downsized and low-cost gyro sensor that are reduced in an environment load can be fabricated. As the particular candidate, a basic research of thinned piezoelectric layer comprised of lithium potassium sodium niobate that is lead-free is currently underway. For the cost reduction in the application area, it is essential that a technique for forming the piezoelectric film on a Si substrate or a glass substrate in a well-controlled state is established.

In the formation of the piezoelectric film, a sputtering method that is industrially proven as a mass-production method is commonly used. The sputtering method is a film formation method configured to plasma-ionize an Ar gas that is a kind of inert gas in a vacuum, allow the Ar ions to come into collision with a sintered body target comprised of the same element composition as that of the piezoelectric film, and allow sputtering particles burst from the target at the time of collision to adhere on the substrate facing the target. This technique is, in principle, configured to form the piezoelectric film under high vacuum, thus oxygen in the oxide thin film is likely to be scarce, consequently it is subjected to the disadvantages of stoichiometrically causing a composition misalignment or the like in comparison with a raw material target.

Also, with regard to various elements of dielectric materials including the piezoelectric film, Pt or the like that is used for an electrode thereof exhibits a high catalyst activity, thus there is a high possibility of inducing reduction of the piezoelectric film comprised of oxide materials by molecules comprised of hydrogen, water (hydroxyl group) and the like that are residual gas in the sputtering formation room.

Furthermore, in the conventional technique, in a lead-free based piezoelectric film corresponding to a basic portion of the piezoelectric element, with regard to local structure of each atom in the vicinity of the surface layer of the piezoelectric film or in the vicinity of the interface between the piezoelectric film and the electrode, change of binding state around each of the atoms is not controlled in a qualitative or quantitative way, thus it is difficult to manufacture a lead-free based piezoelectric element and piezoelectric device that have a high piezoelectric constant in good yield.

Accordingly, it is an object of the invention to provide a piezoelectric element that has an improved piezoelectric property by measuring the binding state around each of the atoms constituting the piezoelectric film so as to carry out indexing, and optimize the manufacturing method of the piezoelectric element based on the measurement results, as well as a piezoelectric device that has a high performance in good yield.

(1) According to one embodiment of the invention, a piezoelectric element comprises:

a substrate; and

a lower electrode layer, a piezoelectric film represented by a general formula of (NaxKyLiz)NbO₃ (0<x≦1, 0<y≦1, 0≦z≦0.2, x+y+z=1) and an upper electrode layer formed on the substrate,

wherein the piezoelectric film has a crystal structure of pseudo-cubic crystal, tetragonal crystal, orthorhombic crystal, monoclinic crystal or rhombohedral crystal, or has a state that at least two of the crystal structures coexist, and

wherein a difference between the maximum value and the minimum value of an energy of Na—K absorption edge measured by an electron energy loss spectroscopy or an X-ray-absorption fine-structure spectroscopy in a direction of the film thickness of the piezoelectric film is not more than 0.8 eV.

In the above embodiment (1) of the invention, the following modifications and changes can be made.

(i) A difference between the maximum value and the minimum value of an energy of K-L₂ absorption edge or/and an energy of K-L₃ absorption edge measured by an electron energy loss spectroscopy or an X-ray-absorption fine-structure spectroscopy in the film thickness direction of the piezoelectric film is not more than 0.8 eV.

(2) According to another embodiment of the invention, a piezoelectric element comprises:

a substrate; and

a lower electrode layer, a piezoelectric film and an upper electrode layer successively formed on the substrate,

wherein the piezoelectric film has a composition of crystal or amorphous represented by a general formula of ABO₃, or the mixture of the crystal and the amorphous in at least a part thereof, where A represents at least one element of Li, Na, K, Pb, La, Sr, Nd, Ba and Bi, B represents at least one element of Zr, Ti, Mn, Mg, Nb, Sn, Sb, Ta and In, and O represents oxygen, and

wherein a difference between the maximum value and the minimum value of an energy of the A atom absorption edge or/and an energy of the B atom absorption edge measured by an electron energy loss spectroscopy or an X-ray-absorption fine-structure spectroscopy in the film thickness direction of the piezoelectric film is not more than 0.8 eV.

In the above embodiment (1) or (2) of the invention, the following modifications and changes can be made.

(ii) The lower electrode layer comprises an electrode layer that is formed of a single layer or a multilayer structure, and is preferentially oriented in a direction perpendicular to the surface of the substrate in the crystal orientation.

(iii) The lower electrode layer comprises an electrode layer comprising Pt or an alloy containing Pt as a main component, or an electrode layer having a multilayer structure including a layer comprising Pt as a main component.

(iv) The lower electrode layer comprises an electrode layer comprising at least one element of Ru, Ir, Sn and In or the oxide of the elements.

(v) The upper electrode layer comprises an electrode layer comprising Pt or an alloy containing Pt as a main component, or an electrode layer having a multilayer structure including a layer comprising Pt as a main component.

(vi) The upper electrode layer comprises an electrode layer comprising at least one element of Ru, Ir, Sn and In or the oxide of the elements.

(vii) The substrate comprises Si, MgO, ZnO, SrTiO₃, SrRuO₃, glass, quartz glass, GaAs, GaN, sapphire, Ge or stainless steel.

(3) According to another embodiment of the invention, a piezoelectric device comprises:

the piezoelectric element according to the embodiment (1) or (2); and

a voltage applying device or a voltage detecting device connected between the lower electrode layer and the upper electrode layer of the piezoelectric element.

(4) According to another embodiment of the invention, a method of manufacturing a piezoelectric element, wherein the piezoelectric element comprises a substrate and a lower electrode layer, a piezoelectric film represented by a general formula of (NaₓK_{y}Li_{z})NbO₃ (0<x≦1, 0<y≦1, 0≦z≦0.2, x+y+z=1) and an upper electrode layer formed on the substrate comprises:

forming the piezoelectric film having a crystal structure of pseudo-cubic crystal, tetragonal crystal, orthorhombic crystal, monoclinic crystal or rhombohedral crystal, or having a state that at least two of the crystal structures coexist;

after the formation of the piezoelectric film, carrying out a heat treatment of the piezoelectric film in a vacuum, in an inert gas atmosphere, in O₂, in an O₂ and inert gas mixed gas, or in the air; and

controlling a difference between the maximum value and the minimum value of an energy of Na—K absorption edge measured by an electron energy loss spectroscopy or an X-ray-absorption fine-structure spectroscopy in the film thickness direction of the piezoelectric film to be not more than 0.8 eV.

In the above embodiment (4) of the invention, the following modifications and changes can be made.

(viii) A difference between the maximum value and the minimum value of an energy of K-L₂ absorption edge or/and an energy of K-L₃ absorption edge measured by an electron energy loss spectroscopy or an X-ray-absorption fine-structure spectroscopy in the film thickness direction of the piezoelectric film is controlled to be not more than 0.8 eV. (5) According to another embodiment of the invention, a method of manufacturing a piezoelectric element, wherein the piezoelectric element comprises a substrate and a lower electrode layer, a piezoelectric film and an upper electrode layer formed on the substrate comprises:

forming the piezoelectric film having a composition of crystal or amorphous represented by a general formula of ABO₃, or the mixture of the crystal and the amorphous in at least a part thereof, where A represents at least one element of Li, Na, K, Pb, La, Sr, Nd, Ba and Bi, B represents at least one element of Zr, Ti, Mn, Mg, Nb, Sn, Sb, Ta and In, and O represents oxygen;

after the formation of the piezoelectric film, carrying out a heat treatment of the piezoelectric film in a vacuum, in an inert gas atmosphere, in O₂, in an O₂ and inert gas mixed gas, or in the air, and

controlling a difference between the maximum value and the minimum value of an energy of the A atom absorption edge or/and an energy of the B atom absorption edge measured by an electron energy-loss spectroscopy or an X-ray-absorption fine-structure spectroscopy in the film thickness direction of the piezoelectric film to be not more than 0.8 eV.

### Effects of the Invention

According to one embodiment of the invention, a piezoelectric element can be stably provided that has a piezoelectric film comprised of lead-free materials such as lithium potassium sodium niobate and that has an excellent piezoelectric property by controlling the local structure (binding state of the atoms) of the piezoelectric film with a high degree of accuracy, as well as a piezoelectric device using the piezoelectric element.

In addition, the piezoelectric element according to the embodiment of the invention makes it possible to prevent the yield from being lowered, when a Pt electrode or a Pt alloy electrode of which crystal orientation is controlled is used as the lower electrode layer of the above-mentioned piezoelectric element, with regard to oxygen deficiency deterioration associated with reduction in the vicinity of the interface between the piezoelectric film and the electrode due to the high catalyst activity thereof; by strictly carrying out quality control based on the atomic-level structure change as to a heterogeneous junction interface such as an interface between the piezoelectric film and the electrode before the formation of fine element by an electron energy-loss spectroscopy or an X-ray-absorption fine-structure spectroscopy capable of carrying out a non-destructive spectroscopic analysis in a minute region of which level is several nm to several tens of nm.

### BRIEF DESCRIPTION OF THE DRAWINGS

The preferred embodiments according to the invention will be explained below referring to the drawings, wherein:

FIG. 1 is a cross-sectional view schematically showing a piezoelectric element according to an embodiment of the invention;

FIG. 2 is an explanatory view schematically showing a sputtering device used at the time of manufacturing the piezoelectric element according to an embodiment of the invention;

FIG. 3 is an example of an X-ray diffraction pattern of 2θ/θ scan in the piezoelectric element according to the embodiment of the invention;

FIG. 4 is an explanatory view schematically showing a crystal structure of an ABO₃ type perovskite structure with a focus on the A atoms (Na, K) in the KNN piezoelectric film according to the embodiment of the invention;

FIG. 5 is an explanatory view schematically showing a crystal structure of an ABO₃ type perovskite structure with a focus on the B atom (Nb) in the KNN piezoelectric film according to the embodiment of the invention;

FIG. 6 is an explanatory view schematically showing a crystal structure of an ABO₃ type perovskite structure with a focus on the O atom (O) in the KNN piezoelectric film according to the embodiment of the invention;

FIG. 7A is a TEM cross-sectional observation image of the KNN piezoelectric film before the heat treatment according to the embodiment of the invention, where EELS measurement positions A, B, C, D and E are also shown;

FIG. 7B is a TEM cross-sectional observation image of the KNN piezoelectric film after the heat treatment according to the embodiment of the invention, where EELS measurement positions F, G, H, I, and J are also shown;

FIG. 8A is a graph showing EELS spectrum results of a K-L₂ absorption edge and a K-L₃ absorption edge at each of the measurement positions shown in FIG. 7A of the piezoelectric film before the heat treatment;

FIG. 8B is a graph showing EELS spectrum results of a K-L₂ absorption edge and a K-L₃ absorption edge at each of the measurement positions shown in FIG. 7B of the piezoelectric film after the heat treatment;

FIG. 9A is a graph showing EELS spectrum results of a Na—K absorption edge at each of the measurement positions shown in FIG. 7A of the piezoelectric film before the heat treatment;

FIG. 9B is a graph showing EELS spectrum results of a Na—K absorption edge at each of the measurement positions shown in FIG. 7B of the piezoelectric film after the heat treatment;

FIG. 10A is a graph showing an energy of a K-L₂ absorption edge and a K-L₃ absorption edge at each of the measurement positions shown in FIG. 7A of the piezoelectric film before the heat treatment;

FIG. 10B is a graph showing an energy of a K-L₂ absorption edge and a K-L₃ absorption edge at each of the measurement positions shown in FIG. 7B of the piezoelectric film after the heat treatment;

FIG. 11A is a graph showing an energy of a K-L₂ absorption edge and a K-L₃ absorption edge relative to the film thickness of the piezoelectric film before the heat treatment;

FIG. 11B is a graph showing an energy of a K-L₂ absorption edge and a K-L₃ absorption edge relative to the film thickness of the piezoelectric element after the heat treatment;

FIG. 12A is a graph showing an energy of a Na—K absorption edge at each of the measurement positions shown in FIG. 7A of the piezoelectric film before the heat treatment;

FIG. 12B is a graph showing an energy of a Na—K absorption edge at each of the measurement positions shown in FIG. 7B of the piezoelectric film after the heat treatment;

FIG. 13A is a graph showing an energy of a Na—K absorption edge relative to the film thickness of the piezoelectric film before the heat treatment;

FIG. 13B is a graph showing an energy of a Na—K absorption edge relative to the film thickness of the piezoelectric film after the heat treatment; and

FIG. 14 is a cross-sectional view schematically showing a piezoelectric device according to an embodiment of the invention.

### DETAILED DESCRIPTION OF THE PREFERRED EMBODIMENTS

A piezoelectric element according to the embodiment of the invention will be described below.

### Structure of Piezoelectric Element

The piezoelectric element 10 has a stacked structure configured to include a substrate 1 and an adhesion layer 2 formed on the surface of the substrate 1, a lower electrode layer 3 formed on the adhesion layer 2, a perovskite type piezoelectric film 4 on the lower electrode layer 3 and an upper electrode layer 5 formed on the piezoelectric film 4, and the piezoelectric film 4 is comprised of a perovskite type oxide represented by a general formula of (NaₓK_{y}Li_{z})NbO₃ (0<x≦1, 0<y≦1, 0≦z≦0.2, x+_{y}+z=1). In addition, the piezoelectric element 10 is configured such that the lower electrode layer 3 is formed so as to be oriented in a predetermined direction and the piezoelectric film 4 is formed so as to be preferentially oriented in a predetermined direction to the lower electrode layer 3.

### Substrate

As a material of the substrate 1, for example, crystal or amorphous of Si, MgO, ZnO, SrTiO₃, SrRuO₃, glass, quartz glass, GaAs, GaN, sapphire, Ge or stainless steel, or a composite thereof can be used. Above all, a Si substrate that is low cost and is industrially proven is preferably used. Further, it is preferable that if the Si substrate is used, an oxide film 6 is formed on the surface of the Si substrate.

As the oxide film 6 formed on the surface of the substrate 1, a thermally-oxidized film formed by a thermal oxidization, a Si oxide film formed by a chemical vapor deposition (CVD) method and the like can be used. Further, the lower electrode layer such as a Pt electrode can be directly formed on the oxide substrate such as a quartz glass substrate, a MgO substrate, a SrTiO₃ substrate, a SrRuO₃ substrate without forming the oxide film 6.

### Lower Electrode Layer

It is preferable that the lower electrode 3 is an electrode layer that is comprised of Pt or an alloy containing Pt as a main component, or an electrode layer having a multilayer structure including a layer comprised of Pt as a main component. In addition, as the materials of the lower electrode layer 3, at least one element selected from the group consisting of Ru, Ir, Sn and In, the oxide of the elements or a compound between Pt and elements contained in the piezoelectric film 4. The lower electrode layer 3 is an important layer for allowing the piezoelectric film 4 to be formed thereon, for example, and is formed by a sputtering method or a deposition method.

In addition, it is preferable that the lower electrode layer 3 is preferentially oriented in a (111) plane direction. The lower electrode layer 3 preferentially oriented in the (111) plane direction (a direction perpendicular to the surface of the substrate 1) becomes a polycrystal having a columnar structure, so that the piezoelectric film 4 formed on the lower electrode layer 3 can be preferentially oriented in a specific plane direction.

It can be adopted that the adhesion layer 2 configured to heighten an adhesion to the substrate 1 is formed between the substrate 1 and the lower electrode layer 3. It is preferable that the adhesion layer 2 includes at least an oxide of Ti, Hf, Zr, Ta, Cr, Mn, and Cu (TiOₓ, HfOₓ, ZrOₓ, TaOₓ, CrOₓ, MnOₓ, and CuOₓ), or an oxide (KO_{X}, NaOₓ, LiOₓ, NbOₓ, and the like) of the elements contained in the piezoelectric film 4.

### Piezoelectric Film

The piezoelectric film 4 is comprised of a perovskite type oxide represented by a general formula of (NaₓK_{y}Li_{z})NbO₃ (0<x≦1, 0<y≦1, 0≦z≦0.2, x+y+z=1) as a main phase. For example, the piezoelectric film 4 can be configured such that the potassium sodium niobate or the lithium potassium sodium niobate (hereinafter collectively referred to as “KNN”) is doped with a predetermined amount of Cu, Ta, V or the like.

The piezoelectric film 4 has a crystal structure of pseudo-cubic crystal, tetragonal crystal, orthorhombic crystal, monoclinic crystal or rhombohedral crystal, or has a state that at least two of the crystal structures coexist, or the piezoelectric film 4 has a composition of crystal or amorphous represented by a general formula of ABO₃, or the mixture of the crystal and the amorphous in at least a part thereof, where A represents at least one element selected from the group consisting of Li, Na, K, Pb, La, Sr, Nd, Ba and Bi, B represents at least one element selected from the group consisting of Zr, Ti, Mn, Mg, Nb, Sn, Sb, Ta and In, and O represents oxygen.

The piezoelectric film 4 is formed by a sol-gel method, a hydrothermal synthesis method, a RF sputtering method, an ion-beam sputtering method, a CVD method, an Aerosol Deposition (A D) method or the like.

### Upper Electrode Layer

Similar to the lower electrode layer 3, it is preferable that the upper electrode 5 is an electrode layer that is comprised of Pt or an alloy containing Pt as a main component, or an electrode layer having a multilayer structure including a layer comprised of Pt as a main component. In addition, as the materials of the upper electrode layer 5, at least one element selected from the group consisting of Ru, Ir, Sn and In, the oxide of the elements or a compound between Pt and elements contained in the piezoelectric film 4. The upper electrode layer 5 is formed by a sputtering method or an evaporation method after the formation of the piezoelectric film 4. The film thickness thereof is formed at the same level as that of the lower electrode layer 3.

### Control of Piezoelectric Film

Conventionally, a measurement in relation to an atomic level local structure (a binding state of atoms) in a local region in the piezoelectric film (for example, the vicinity of the surface of the piezoelectric film, the vicinity of the center of the piezoelectric film, the vicinity of the interface between the piezoelectric film and the electrode and the like) is not carried out, and the piezoelectric film is formed without evaluating the change in the local structure, thus a piezoelectric element having a desired high piezoelectric constant could not be obtained with high reproducibility.

Namely, in the case of the conventional evaluation method of the piezoelectric film, the local structure around the atoms constituting the piezoelectric film (the binding state of the atoms) could not be measured, thus it is not specified whether the change in the piezoelectric property is caused due to raw materials during the formation of the piezoelectric film, due to the residual gas, or due to a modification treatment after the formation thereof, consequently it is difficult to further enhance the piezoelectric constant and to stably produce the piezoelectric film.

For example, as the conventional evaluation method in relation to change of the local region of the piezoelectric film, an analysis of elements such as niobium (Nb), potassium (K), sodium (Na) that are a main component of the KNN piezoelectric film is carried out by an electron probe microanalyzer (EPMA) or the like, but the above-mentioned evaluation (measurement) method can measure only a composition (ratio) instead of the local structure of the atoms in the piezoelectric film (the binding state of the atoms), thus it is difficult to carry out the indexing of the local structure around the atoms constituting the lead-free piezoelectric film (the binding state of the atoms).

In addition, a X-ray diffraction method that is a general method of a structural analysis can analyze, in principle, only a long-period order structure extending into a wide region, thus the method is unsuitable for an evaluation method configured to measure the local structure around the specified atoms that has a size of the level of several atom diameters in a narrow region (the binding state of the atoms) so as to selectively control the local structures.

For example, in a direction of the film thickness of the KNN piezoelectric film, the local structure (the binding state) and the structural change around the specified atoms constituting the piezoelectric film, such as niobium (Nb), potassium (K), sodium (Na), oxygen (O), could not be definitely measured, and the indexing thereof could not be carried out.

That is, until now, it remains unclear how the manufacturing condition such as an input electric power and a temperature for the formation of the piezoelectric film, a change in the distance between the substrate and the raw material target due to the sputtering, a heat treatment after the formation of the piezoelectric film exerts an influence on the binding state around each of the atoms in the piezoelectric film formed and a quantitative distribution in the whole of the piezoelectric film, and how those are varied by the above-mentioned manufacturing condition. Therefore, a control or improvement of the growth process (the manufacturing condition and the like) of the piezoelectric film based on the structure measurement results at the level of atom in the piezoelectric film has not been carried out.

Accordingly, in order to strictly control the binding state around each of the atoms and the structural distribution of the whole piezoelectric film, a mapping measurement is carried out from the surface of the piezoelectric film so as to extend into the interface between the lower electrode layer by using an electron energy loss spectroscopy (hereinafter referred to as “EELS”) measurement equipment or an X-ray-absorption fine-structure (hereinafter referred to as “XAFS”) analysis equipment that is capable of carrying out a non-destructive spectroscopic analysis in a minute region. In particular, the local structure (the binding state) or the structural change around each of the atoms such as niobium (Nb), potassium (K), sodium (Na), oxygen (O) is measured, thereby it becomes possible to set the formation temperature, the type of sputtering operation gas, the gas pressure, the degree of vacuum, the input electric power, the heat treatment after the formation and the like of the piezoelectric film under optimum conditions, and the piezoelectric property can be enhanced.

In particular, so as to control the local structure (the binding state) around the atoms of potassium (K), sodium (Na), niobium (Nb) and oxygen (O), an energy value of K-L (K-L₂, K-L₃) absorption edge or an energy value of Na—K absorption edge that are closely associated with the change in the local structure (the binding state) around the atoms is subjected to the EELS analysis or the XAFS analysis so as to be used as the control values for controlling the local structure (the binding state) around the atoms. In addition, a distribution of the local structure (the binding state) around the atoms in a direction of the film thickness of the piezoelectric film comprised of the lithium potassium sodium niobate such as a distribution thereof in the vicinity of the surface and center of the piezoelectric film, the vicinity of the interface between the lower electrode and the like is measured in detail, thereby it becomes possible to control the change in an energy of each absorption edge in a direction of the film thickness at the level of nanometer.

That is, a relationship between the energy of each absorption edge and the piezoelectric property or the dielectric property is clarified, and the change in energy of the constituent atom absorption edge in a direction of the film thickness that is corresponding to the distribution of the local structure (the binding state) around the atoms constituting the piezoelectric film is controlled so as to be lessened (a difference between the maximum value and the minimum value of an energy of the constituent atom absorption edge is controlled so as to fall within the certain definite range), thereby it becomes possible to stably produce the piezoelectric film with high reproducibility.

### Atomic Structure Measurement of Piezoelectric Film

As one example of measurements for carrying out an indexing of the distribution of the local structure (the binding state) around the atoms constituting the piezoelectric film 4 according to the invention, the EELS measurement will be explained. The EELS means a measurement of an electron energy distribution spectrum scattered by an energy of Eᵢ-Eₖ that is observed when the piezoelectric film disposed in the ultra-high vacuum is irradiated with electrons having a high energy, the primary electrons having an energy of Eᵢ excite the inner shell of each constituent atom in the piezoelectric film, and emission of the inner shell electrons occurs, the inner shell electrons being in a state of energy of Eₖ that is determined by atomic species.

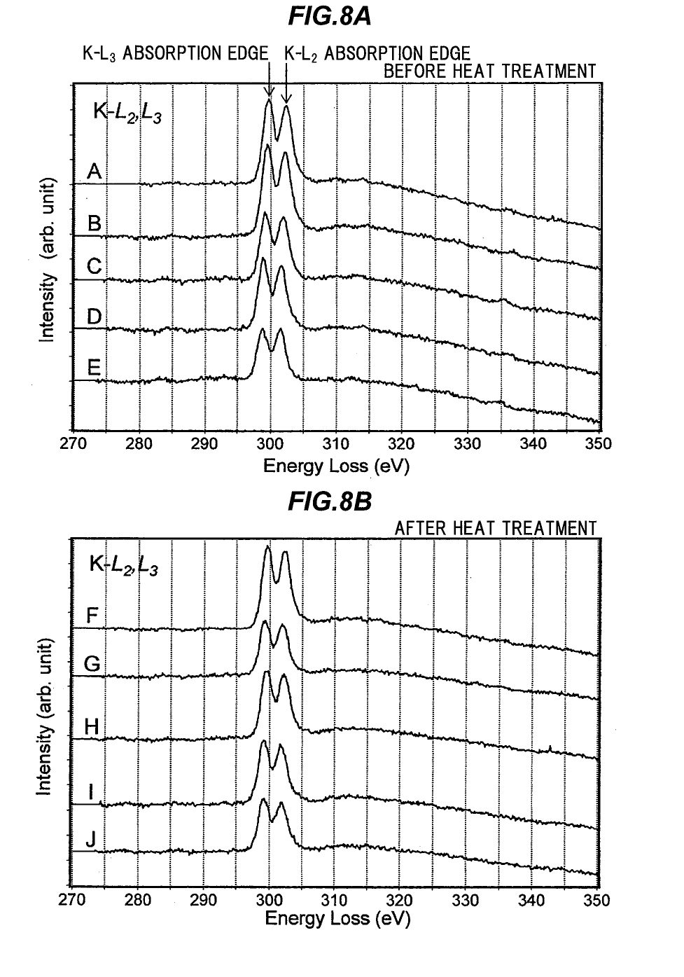

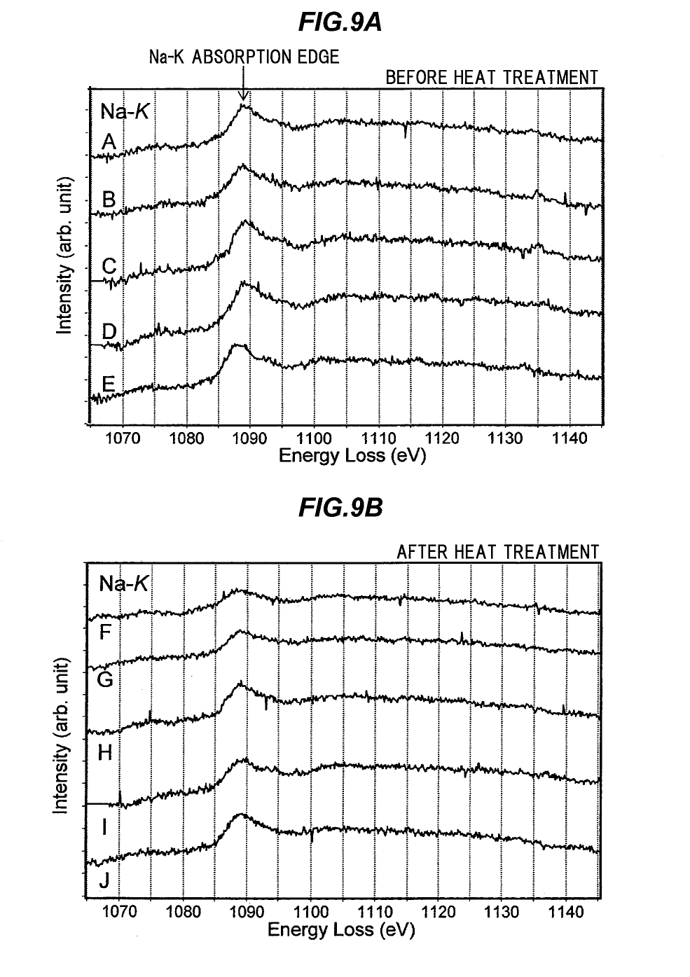

As shown in FIGS. 8, 9, the actual EELS measurement is measured as a fine oscillatory structure that is observed in a region of±several tens of eV in the vicinity of the absorption edge (loss peak) and in a region extending into several hundreds of eV in the high energy loss side. That is, if the horizontal axis is set to show an energy loss and the vertical axis is set to show the number of electron detected (an intensity), a profile of the EELS spectrum can be represented. Here, the absorption edge corresponding to an electron loss energy of the maximum peak intensity of the spectrum is different dependent on the atom, and an energy of the absorption edge is changed (a chemical shift) according to the binding state between the atoms and existence or non-existence of oxygen deficiency. Namely, it becomes possible to carry out the indexing of the binding state between the atoms from the change in an energy of the absorption edge and to control so as to realize a desired state.

As mentioned above, with regard to the piezoelectric film, an energy of the Na—K absorption edge and an energy of K-L₂ absorption edge or/and an energy of K-L₃ absorption edge that show the binding state around Na atom and K atom of the KNN piezoelectric film can be measured by using the EELS measurement equipment or the XAFS analysis device. In addition, the vicinity of the surface of the piezoelectric film or the vicinity of the interface between the Pt lower electrode is subjected to a mapping measurement by the EELS or the XAFS spectroscopy, thereby it becomes possible to estimate a distribution of the local structure (the binding state) around the atoms constituting the piezoelectric film based on the change in an energy of the Na absorption edge and the K absorption edge. As a result, in the piezoelectric film manufactured, with regard to an atomic structure distribution in a direction of the film thickness (the vicinity of the surface and center of the piezoelectric film, the vicinity of the interface between the lower electrode and the like), the uniformity of the binding state of each constituent element (atom) in the piezoelectric film is indexed, and the manufacturing condition is optimized based on the change in an energy of each atom absorption edge so as to be strictly controlled, thereby it becomes possible to stably produce the piezoelectric film exhibiting a high piezoelectric constant with high reproducibility.

### Atomic Structure Control of Piezoelectric Film

As mentioned above, when the binding state between the atoms is indexed according to the change in an energy of constituent atom absorption edge in a direction of the film thickness of the piezoelectric film and an analysis is carried out, it turns out that a composition mismatch of the piezoelectric film occurs in the conventional piezoelectric element, thus the enhancement of the piezoelectric constant is difficult. It can be considered that the composition mismatch is caused by the fact that the change in an energy of constituent atom absorption edge in a direction of the film thickness of the piezoelectric film 4 is large (a difference between the maximum value and the minimum value of an energy of constituent atom absorption edge in a direction of the film thickness is large).

It is considered that the change in an energy of constituent atom absorption edge is also affected by the number of oxygen that is the nearest neighbor atom of each atom. Namely, the local structure (the binding state) of Na—O and K—O of the piezoelectric film is controlled, thereby it becomes possible to control the change in an energy of constituent atom absorption edge.

It is considered that the reason why conventionally a difference between the maximum value and the minimum value of an energy of constituent atom absorption edge is large is because the number of oxygen that is the nearest neighbor atom is deficient. It is considered that normally, if the film formation of the piezoelectric film is carried out by the sputtering method, the film formation is carried out under high vacuum, thus a state that oxygen in the piezoelectric film is deficient is caused, and simultaneously since Pt or the like used for the lower electrode layer and the upper electrode layer exhibits a high catalyst activity, reduction of the oxide materials constituting the oxidized film and the adhesion film is induced by molecules comprised of hydrogen gas, water (hydroxyl group) and the like that remain in the room at the time of the film formation, thus the oxygen deficiency in the piezoelectric film 4 is caused.

That is, for the purpose of decreasing the change in an energy of constituent atom absorption edge in a direction of the film thickness of the piezoelectric film, namely decreasing a difference between the maximum value and the minimum value of an energy of constituent atom absorption edge in a direction, it is needed that the local structure (the binding state) of Na—O and K—O of the piezoelectric film is controlled, namely sufficient oxygen is compensated in the piezoelectric film in which oxygen is deficient by the sputtering film formation.

As a result of honestly having investigated the method for improving this, it is recognized that it is effective to apply a heat treatment to the piezoelectric film 4 after the formation.

As the heat treatment, it is necessary to be maintained at the temperature of higher than at least 700 degrees C., and it is more preferably that the heat treatment is carried out at 800 degrees C. As the maintaining time, it is necessary to be maintained for longer than at least 1 hour, and it is more preferably that the heat treatment is carried out for 2 hours. As the atmosphere of the heat treatment, it is preferable that the heat treatment is carried out in a vacuum, in an inert gas atmosphere, in O₂, in an O₂ and inert gas mixed gas, or in the air. Other than the above-mentioned atmosphere, a mixed gas atmosphere including at least one of O₃, N₂O and H₂O can be adopted. The heat treatment can be carried out by heat radiation using an infrared lamp, heat conduction using heater heating via a heat exchanger plate or the like. It is preferable that a method for setting the above-mentioned heat treatment state is configured to firstly allow the space in which the piezoelectric film is held to become the above-mentioned atmosphere, to elevate the temperature from the room temperature to 800 degrees C. for not more than 24 hours, and to carried out the heat treatment at 800 degrees C. for 2 hours.

As mentioned above, the heat treatment is applied after the formation of the piezoelectric film, thereby oxygen is compensated from the heat treatment atmosphere and the oxide used as materials for the oxidized film 6 and the adhesion layer 2 of the piezoelectric element 10, and the local structure (the binding state) of Na—O and K—O of the piezoelectric film is controlled in a good state, thus it becomes possible to decrease a difference between the maximum value and the minimum value of an energy of constituent atom absorption edge in a direction of the film thickness of the KNN piezoelectric film.

In the present invention, the KNN constituting the piezoelectric film 4 is comprised of the perovskite structure of ABO₃ type oxide, it is known that the composition ratio between K and Na that are located in an A site of the ABO₃ type exerts an influence on the piezoelectric property and the dielectric property (refer to Reference Literature 1). That is, it is expected that various properties of the piezoelectric film 4 are changed dependent on the local structure (the binding state) around the A site atoms (K and Na).

Namely, in order to enhance the properties of the piezoelectric film 4 and ensure the production stability of the piezoelectric film 4, it becomes important to control the change in an energy of the K and Na absorption edges of the EELS spectrum that represents the local structure (the binding state) around the K and Na atoms located in the A site. In particular, it is preferable that a difference between the maximum value and the minimum value of an energy of the Na—K absorption edge or the K-L₂ or/and K-L₃ absorption edge in a direction of the film thickness of the piezoelectric film is decreased.

It is preferable that the difference between the maximum value and the minimum value of an energy of the Na—K absorption edge or the K-L₂ or/and K-L₃ absorption edge in a direction of the film thickness of the piezoelectric film is not more than 0.8 eV. The difference is controlled to be not more than 0.8 eV, thereby it becomes possible to enhance the piezoelectric property and the dielectric property.

Referential Literature 1: K. Shibata, K. Suenaga, K Watanabe, F. Horikiri, A Nomoto, and T. Mishima, Jpn. J. Appl. Phys. 50 041503-1.

Verification of the oxygen deficiency due to the film formation, and the oxygen compensation due to the above-mentioned heat treatment and improvement of the change in an energy of the absorption edge will be described in detail in Examples.

As mentioned above, the local structure (the binding state) around the constituent atoms in a direction of the film thickness of the piezoelectric film is measured and indexed, thereby the optimum manufacturing condition (heat treatment condition) is derived, and the upper electrode layer 5 is formed on the piezoelectric film 4 after the heat treatment is carried out under the optimum condition, thereby it becomes possible to manufacture the piezoelectric element 10 exhibiting a high piezoelectric constant.

### Piezoelectric Device

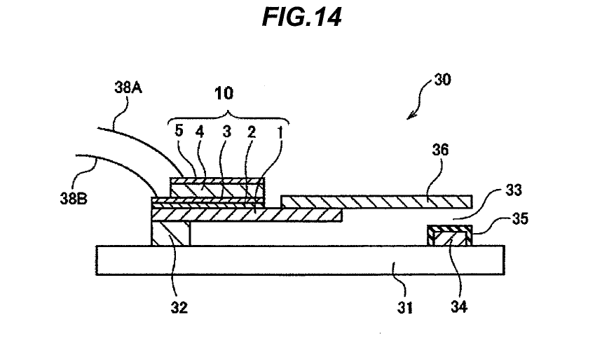

In addition, the piezoelectric element 10 according to the embodiment shown in FIG. 14 is formed so as to have a predetermined shape, and a voltage applying device or a voltage detecting device is installed between the lower electrode layer 3 and the upper electrode layer 5 of the piezoelectric element 10 formed, thereby various piezoelectric devices 30 such as an actuator, a sensor can be manufactured. The crystal orientation of the lower electrode layer 3 and the piezoelectric film 4 in these piezoelectric devices 30 is stably controlled, thereby enhancement of piezoelectric property and stabilization of the piezoelectric element 10 and the piezoelectric device 30 can be realized, and a micro device having a high performance can be provided at a low cost. In addition, the piezoelectric element according to the invention is a piezoelectric element including the piezoelectric film that is lead-free, thus the piezoelectric element according to the invention is mounted therein, thereby a small size system device, for example, a micro electro mechanical system (MEMS) device, such as a small size motor, sensor actuator that is capable of reducing environment load and has a high performance can be realized.

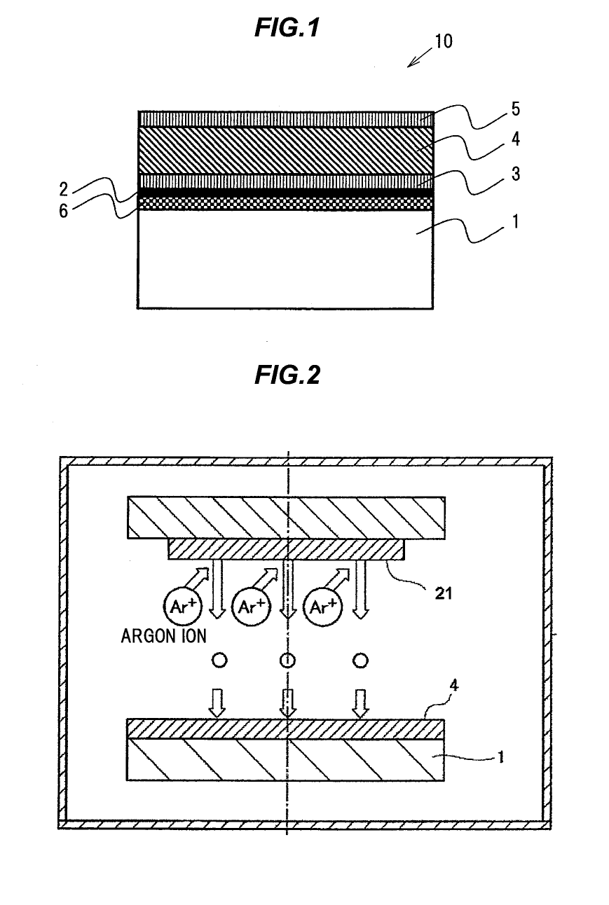

FIG. 14 is a cross-sectional view schematically showing a piezoelectric device according to another embodiment of the invention. The piezoelectric device 30 according to the embodiment shows a case that the piezoelectric element 10 according to the embodiment shown in FIG. 1 is applied to a variable capacitor. The piezoelectric device 30 includes a device substrate 31, an insulation layer 32 formed on the device substrate 31, and a piezoelectric element 10 formed on the insulation layer 32 and having a structure similar to that shown in FIG. 1 (the oxidized film 6 is not shown). The device substrate 31 and the insulation layer 32 function as a supporting member that supports one end portion of the piezoelectric element 10. The piezoelectric film element 10 is configured such that the adhesion layer 2, the lower electrode 3 and the piezoelectric film 4 are formed on the substrate 1, and the substrate 1 is extended in another end portion (free end portion) of the piezoelectric element 10, and an upper capacitor electrode 36 is formed on the extending part of the substrate 1 so as to be projected. A lower capacitor electrode 34 is formed on the device substrate 31 so as to be located below the upper capacitor electrode 36 via a space 33, and an insulation layer 35 comprised of SiN or the like is formed on the surface of the lower capacitor electrode 34.

In addition, when electric voltage is applied to the upper electrode 5 and the lower electrode 3 via each of bonding wires 38A, 38B, the end portion of the piezoelectric element 10 is displaced, in association with this, the upper capacitor electrode 36 is displaced in the vertical direction. Due to the displacement of the upper capacitor electrode 36, the capacitor between the upper capacitor electrode 36 and the lower capacitor electrode 34 is changed, so that the piezoelectric device 30 operates as a variable capacitor.

A voltage applying device (not shown) is connected between the lower electrode layer 3 and the upper electrode 5 of the piezoelectric element 10 according to the embodiment, thereby an actuator as a piezoelectric device can be obtained. A voltage is applied to the piezoelectric element of the actuator so as to deform the piezoelectric element, thereby various members can be operated. The actuator can be used for, for example, an ink-jet printer, a scanner, an ultrasonic generator, and the like.

The piezoelectric element 10 according to the embodiment is formed so as to have a predetermined shape and the voltage applying device (not shown) is connected between the lower electrode layer 3 and the upper electrode 5, thereby a sensor as a piezoelectric device can be obtained. When the piezoelectric element of the sensor is deformed in association with change in some kind of physical quantity, a predetermined voltage occurs depending on the amount of displacement of the deformation, thus the voltage is detected by the voltage detecting device, thereby various physical quantities can be measured. The sensor includes a gyro sensor, an ultrasonic sensor, a pressure sensor, a velocity-acceleration sensor, and the like.

### EXAMPLES

Examples according to the invention will be explained below.

FIG. 1 is a cross-sectional view schematically showing a substrate with a piezoelectric element. In the Example, the piezoelectric element 10 was manufactured such that the adhesion layer 2 was formed directly on the substrate or on the substrate via the oxidized film 6, and the lower electrode layer 3, the piezoelectric film 4 comprised of a perovskite type potassium sodium niobate (hereinafter referred to as “KNN”) and the upper electrode layer 5 were formed on the adhesion layer 2. The content of an organic molecule and a molecule having a hydroxyl group in the piezoelectric film 4 is changed dependent on the crystal condition, the composition and the manufacturing condition of the piezoelectric film 4. Hereinafter, a manufacturing method will be explained in detail.

First, a thermally-oxidized film (the oxidized film 6) was formed on the Si substrate 1, and the adhesion layer 2 comprised of a Ti film of 2 nm in thickness and the lower electrode layer 3 comprised of a Pt or Au thin film, or a lamination of both of the thin films, or a thin film of an alloy of Pt and Au, of 200 nm in thickness were formed thereon. A sputtering method was used for the formation of the lower electrode layer 3. A metal target was used as the target for the sputtering, the sputtering input electric power at the film formation was 100 W, and as a sputtering gas, an Ar 100% gas, or an Ar and O₂ mixed gas, or at least one inert gas mixed gas, the inert gas being selected from the group consisting of He, Ne, Kr and N₂ gas. In addition, the lower electrode layer 3 of a polycrystalline thin film comprised of Pt or Au was formed at the substrate temperature of 350 degrees C.

Next, the KNN piezoelectric film having a film thickness of 3 μm was formed on the lower electrode layer 3 as the piezoelectric film 4 by using a RF magnetron sputtering device shown in FIG. 2. In addition, the formation temperature of the KNN piezoelectric film was in a range of 400 to 500 degrees C., and the sputtering film formation was carried out by using a plasma due to an Ar and O₂ (5:5) mixed gas, or an Ar gas, or at least one inert gas mixed gas, the inert gas being selected from the group consisting of He, Ne, Kr and N₂ gas. In addition, as the raw material target 21, a ceramic target comprised of (NaₓK_{y}Li_{z})NbO₃ (x=0.5, y=0.5, Z=0) that was controlled to be an appropriate composition ratio was used, and the film formation was carried out until the film thickness became 1 to 5 μm.

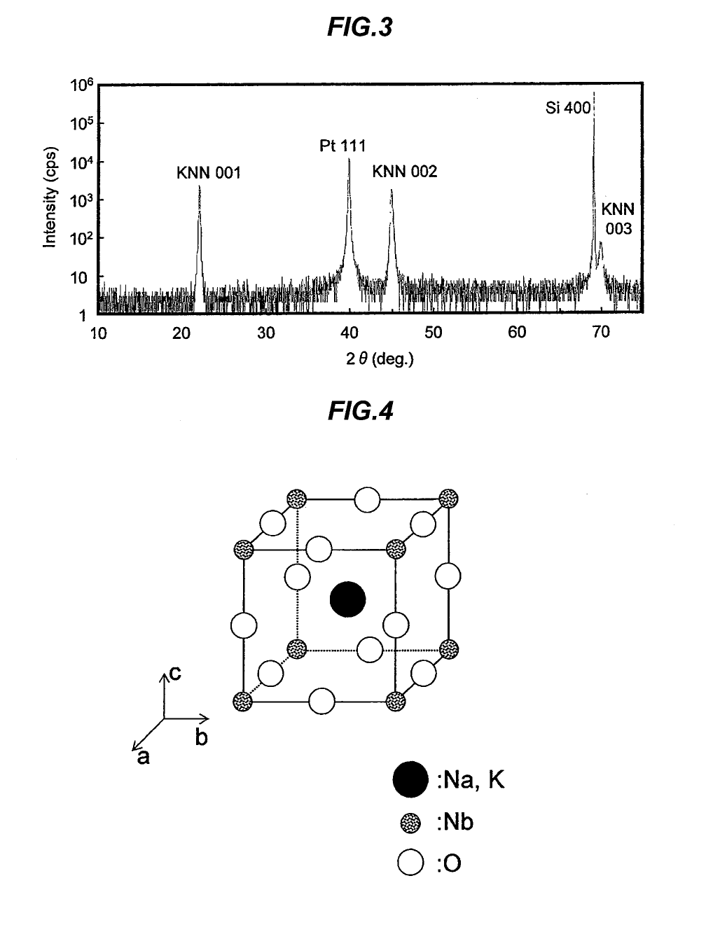

With regard to the KNN piezoelectric film 4 formed as mentioned above, the cross-sectional shape thereof was observed by using an electron scanning microscope or the like, as a result, it was found that the organization was configured to have a columnar structure, and the crystal structure was examined by using a general X-ray diffractometer, as a result, it was found that the lower electrode layer 3 of a polycrystalline thin film comprised of Pt or Au that was formed by carrying out the substrate heating was oriented in the (111) plane direction and in a direction perpendicular to the surface of the substrate as shown in the X-ray diffraction pattern (2θ/θ scan measurement) of FIG. 3.

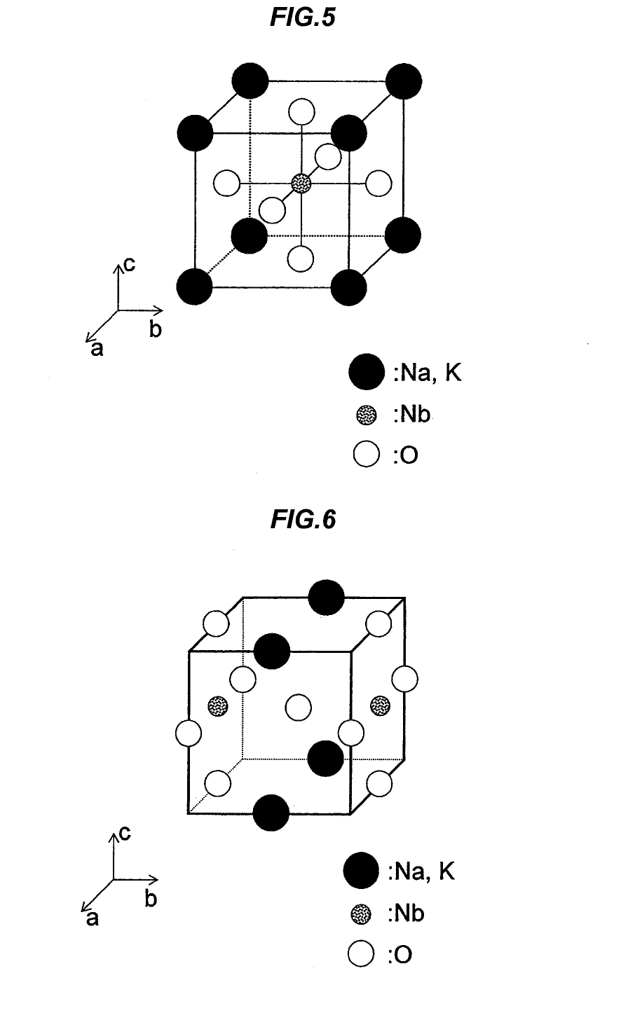

The piezoelectric film 4 comprised of the KNN was formed on the lower electrode layer 3 comprised of Pt preferentially oriented in the (111) plane direction, as a result, it was found that the piezoelectric film 4 formed was a polycrystalline thin film having a perovskite type crystal structure of pseudo-cubic crystal shown in FIGS. 4, 5 and 6. Further, FIG. 4 shows a unit lattice with a focus on the Na and K atom, FIG. 5 shows a unit lattice with a focus on the Nb atom, and FIG. 6 shows a unit lattice with a focus on the O atom. In addition, as can be seen from the X-ray diffraction pattern of FIG. 3, only the diffraction peaks of 001, 002, 003 can be confirmed, thus the piezoelectric film 4 comprised of the KNN was preferentially oriented in a state of approximately (001).

After that, the piezoelectric element 10 was subjected to pretreatment in order to be suitable for the EELS measurement.

First, a carbon protect film was formed for the purpose of protecting the outermost surface of the piezoelectric film 4 by a deposition device and a W protect film was coated in a FIB processing device. Next, analysis parts were picked up by a microsampling method, so as to be sliced into thin sections by a FIB processing. After that, removal of FIB damage layer was carried out by a low acceleration finishing of an acceleration voltage of 5 kV. Here, a processing device actually used is a focused ion beam processing device manufactured by Hitachi High-Technologies Corporation and sold by the trade name of “FB-2000” and Dual Beam (FIB/SEM) System manufactured by FEI and sold by the trade name of “NOVA 200”.

### Measurement 1

Next, analysis points in the piezoelectric film 4 of the piezoelectric element 10, that is, in order to determine the electronic irradiation position at the level of nanometer, high-resolution observation image data by a transmission electron microscope (hereinafter referred to as “TEM”) were obtained. The TEM observation device was a field-emission transmission electron microscope manufactured by JEOL Ltd. and sold by the trade name of “JEM-2010F”, and an electronic irradiation by an acceleration voltage of 200 kV was carried out. Further, as a detector for TEM, a CCD camera manufactured by Gatan Inc. and sold by the trade name of “Ultra Scan” was used. In addition, in the EELS measurement, the same device as the device for TEM measurement was used and an acceleration voltage was 200 kV. Loss energy spectrum of electrons generated from irradiation samples was measured by a spectrometer exclusively used for the EELS manufactured by Gatan Inc. and sold by the trade name of “Enfina 1000”.

With regard to each atom constituting the piezoelectric film 4 comprised of the KNN according to Example, namely potassium (K), sodium (Na), niobium (Nb), and oxygen (O), a fine structure analysis is carried out in great detail by the EELS measurement in the vicinity of absorption edge, thereby information about arrangement and chemical bond of the atoms constituting the piezoelectric film 4 can be obtained. As to details of atomic structure analysis by the EELS measurement, refer to the following Referential Literatures.

Referential Literature 2: KOBELCO research institute, “Structure Analysis of Functional Materials by EELS”, Technical Note “KOBELNICUS”, Vol. 11, October 2002, p.12

Referential Literature 3: Eiji Tanabe, Yasuyuki Kitano, Yuuki Morishita, Masahide Honda, “Structure Analysis of Amorphous Materials by Electron Energy Loss Spectroscopy (EELS)”, Hiroshima Prefectural Western Region Industrial Research Center, Research Report No. 48, 2005, p. 36

Profile of loss energy spectrum is measured with a high degree of accuracy, thereby it becomes possible to find out the local structure (the binding state) around the specific atoms constituting the piezoelectric film 4 comprised of the KNN and the change in the structural distribution in the film. The above-mentioned change in the structural distribution in the film at the level of atom closely relates to the piezoelectric property and the dielectric property, thus as to an influence that existence or non-existence of the heat treatment after the film formation of the lead-free piezoelectric film 4 comprised of the KNN of a perovskite type in the invention exerts on the piezoelectric property, the local structure (the binding state) around the atoms was analyzed by using the above-mentioned measurement methods, and verification was carried out.

### Measurement 2

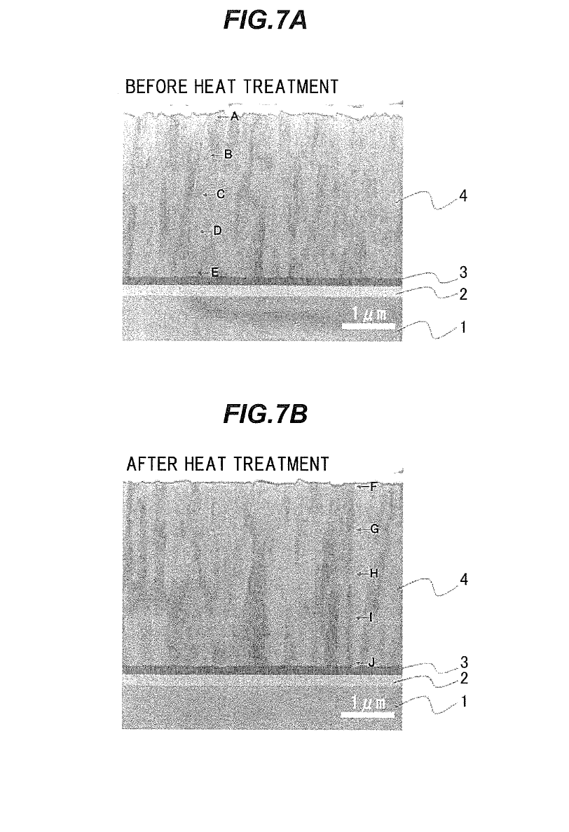

FIGS. 7A, 7B show a TEM cross-sectional observation image of the piezoelectric element 10 manufactured by Example. Here, FIG. 7A is a TEM cross-sectional observation image of the KNN piezoelectric film 4 before the heat treatment, and FIG. 7B is a TEM cross-sectional observation image of the KNN piezoelectric film 4 after the heat treatment was applied to the piezoelectric film 4 at 800 degrees C. for 2 hours in N₂O atmosphere in which the temperature was elevated from the room temperature to 800 degrees C. for not more than 24 hours. In Example, the heat treatment was carried out by heat radiation using an infrared lamp. Further, the surface of the KNN piezoelectric film 4 is located at the upper side of the drawing, and the substrate 1 is located at the lower side thereof. In the EELS measurement in the invention, a mapping measurement was carried out from the vicinity of the surface of the KNN piezoelectric film 4 to the vicinity of the interface between the Pt lower electrode 3 along A, B, C, D, E or F, G, H, I, J in FIG. 7A or FIG. 7B.

FIGS. 8A, 8B show the EELS spectrum of the L absorption edge (K-L₂, K-L₃) in K atom that is one of the constituent atoms of the piezoelectric film 4 as actual measurement results of the EELS. FIG. 8A shows the EELS spectrum before the heat treatment and FIG. 8B shows the EELS spectrum after the heat treatment. The A to E or the F to J in the drawings are the EELS spectrum of the K-L (K-L₂, K-L₃) absorption edge corresponding to the measurement positions of the piezoelectric film 4 shown in FIGS. 7A, 7B as the TEM observation image. As two peaks (absorption edges), L₂ (2p_{1/2}) and L₃ (2p_{3/2}) are observed, but the difference between the two peaks is caused by a transition difference between energy levels generated after the inner shell electrons are excited, thus both of the two peaks include almost the same information of the binding state around the K atom.

The KNN piezoelectric film 4 according to the Example is comprised of a perovskite structure of an ABO₃ type oxide, and it is known that the composition ratio between K and Na that are located in an A site of the ABO₃ type exerts an influence on the piezoelectric property and the dielectric property. That is, it is expected that various properties of the piezoelectric film 4 are changed dependent on the local structure (the binding state) around the A site atoms (K and Na). Namely, in order to enhance the properties of the piezoelectric film 4 and ensure the production stability of the piezoelectric film 4, it becomes important to control the change in an energy of the K and Na absorption edges of the EELS spectrum that represents the local structure (the binding state) around the K and Na atoms located in the A site. In particular, it is preferable that a difference between the maximum value and the minimum value of an energy of the Na—K absorption edge or the K-L₂ or/and K-L₃ absorption edge in a direction of the film thickness of the piezoelectric film is decreased.

Accordingly, the EELS spectrum of the K absorption edge in Na atom that is another A site atom of the KNN piezoelectric film 4 was measured. The results are shown in FIGS. 9A, 9B. Here, FIG. 9A shows the EELS spectrum before the heat treatment and FIG. 9B shows the EELS spectrum after the heat treatment. Regardless of the measurement positions, an energy transition of electrons of the Na—K absorption edge is one, thus the peak is found out at a rate of one per about 1089 eV. However, in FIG. 9A before the heat treatment, it is recognized that the Na—K absorption edge is shifted to a lower energy side in the measurement point E. Generally, in an oxide, if the number of oxygen atoms around the metal atom is decreased, that is, the oxygen deficiency is progressed, the absorption edge of the EELS and the XAFS may be shifted to a lower energy side or new absorption edge may be observed in the lower energy side. In other words, in the piezoelectric film 4 according to the Example comprised of the KNN before the heat treatment, it can be estimated that O (oxygen) atoms around Na atom are decreased in the vicinity of the interface between the lower electrode layer 3, and the oxygen deficiency around Na atom is remarkable.

### Measurement 3

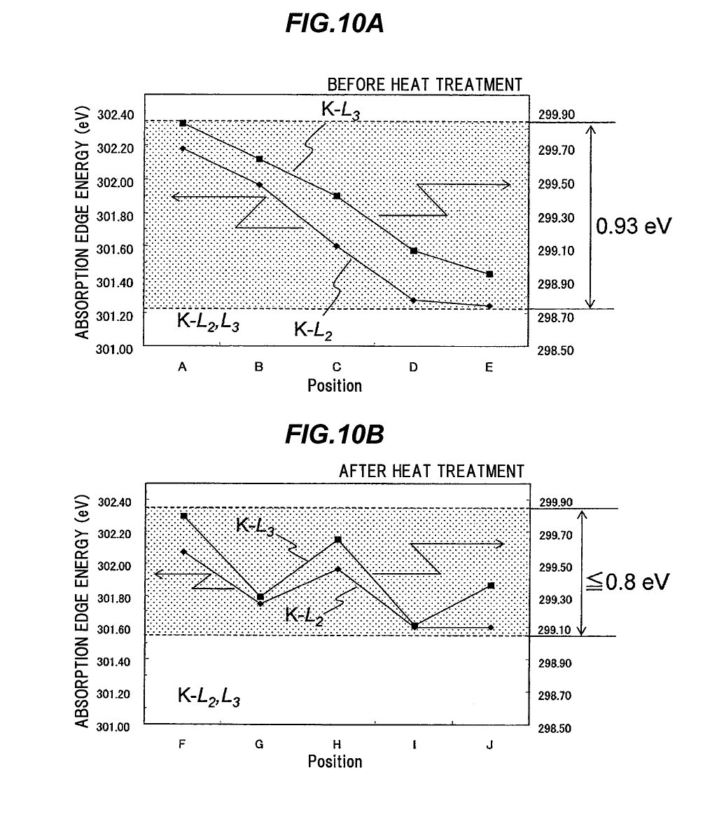

FIGS. 10A, 10B show the change in an energy of the K-L₂ absorption edge and the K-L₃ absorption edge in a direction of the film thickness of the KNN piezoelectric film (in the positions of the A to E and the F to J in FIGS. 7A, 7B) based on the EELS spectrum of K-L absorption edge in FIGS. 8A, 8B. Here, FIG. 10A shows a case before the heat treatment (a case that the heat treatment is not carried out) and FIG. 10B shows a case after the heat treatment (a case that the heat treatment is carried out).

FIG. 10A of “before the heat treatment” shows that a difference of about 0.9 to 1 eV is observed between the maximum value and the minimum value of an energy of the absorption edge of both of the K-L₂ absorption edge and the K-L₃ absorption edge in the vicinity of the surface of the KNN piezoelectric film 4 (the position of A) and in the vicinity of the interface between the KNN piezoelectric film 4 and the Pt lower electrode layer 3 (the position of E). In addition, it is recognized that the K-L absorption edge is almost monotonically decreased toward the Pt lower electrode layer 3 and is shifted to a lower energy in the vicinity of the interface between the Pt lower electrode layer 3.

On the other hand, as can be seen from FIG. 10B, a difference between the maximum value and the minimum value of an energy of the K-L (K-L₂, K-L₃) absorption edge in the region from the vicinity of the surface of the KNN piezoelectric film 4 after the heat treatment (the position of F) to the vicinity of the interface between the Pt lower electrode layer 3 (the position of J) is not more than 0.8 eV that is smaller than the difference between the maximum value and the minimum value of an energy of the K-L (K-L₂, K-L₃) absorption edge in the region from the vicinity of the surface of the KNN piezoelectric film 4 before the heat treatment (the position of A) to the vicinity of the interface between the Pt lower electrode layer 3 (the position of E). That is, it shows that the heat treatment was carried out at 800 degrees C. for 2 hours, thereby the difference between the maximum value and the minimum value of an energy of the K-L (K-L₂, K-L₃) absorption edge in a direction of the film thickness of the KNN piezoelectric film 4 could be decreased to not more than 0.8 eV.

That is, it shows that by the heat treatment after the formation of the KNN piezoelectric film 4, the oxygen deficiency was compensated by oxygen from the heat treatment atmosphere and an oxide on the substrate, and the local structure (the binding state) around K atom of the KNN piezoelectric film 4 was improved so as to be a uniform distribution over the region from the surface of the KNN piezoelectric film 4 to the interface between the Pt lower electrode layer (i.e., the distribution in a direction of the film thickness of the KNN piezoelectric film 4 was improved so as to be uniform).

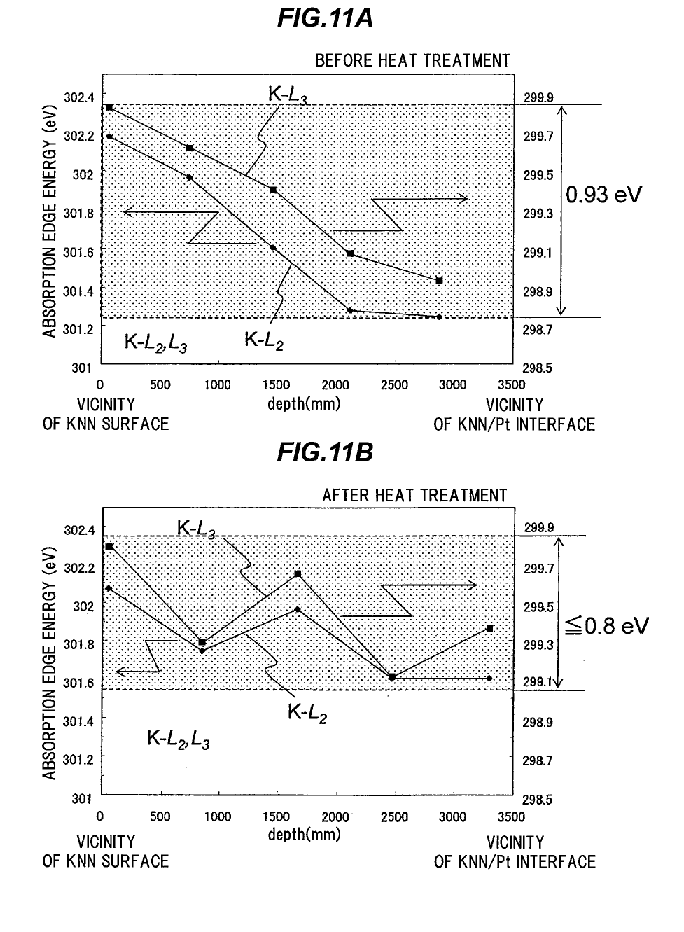

In addition, study in relation to the K-L (K-L₂, K-L₃) absorption edge relative to the film thickness of the KNN piezoelectric film 4 was carried out based on the TEM observation image. The film thickness of the KNN piezoelectric film 4 is about 3 μm similar to the above-mentioned Example. FIG. 11A shows the change in an energy of the K-L (K-L₂, K-L₃) absorption edge of the EELS relative to the film thickness of the KNN piezoelectric film 4 before the heat treatment.

It was recognized that the energy of the K-L₂ and K-L₃ absorption edge was almost monotonically decreased relative to the film thickness in proportion to nearing the interface between the Pt lower electrode layer 3. If the change represents the decrease in the coordination number of oxygen that is the nearest neighbor atom around K atom, it is expected that if the heat treatment is not carried out, in the oxygen deficiency site around the K atom of the KNN piezoelectric film 4, the oxygen deficiency number is almost continuously increased in proportion to nearing the interface between the Pt lower electrode layer 3.

On the other hand, as a result of the heat treatment being carried out, as shown in FIG. 11B, the continuous change in an energy of the K-L (K-L₂, K-L₃) absorption edge relative to the film thickness of the KNN piezoelectric film 4 becomes unclear, but a difference between the maximum value and the minimum value of an energy of the K-L (K-L₂, K-L₃) absorption edge in a direction of the film thickness of the KNN piezoelectric film 4 is decreased. As a result of studying a correlation with the piezoelectric property, it was confirmed that if the difference between the maximum value and the minimum value of an energy of the K-L (K-L₂, K-L₃) absorption edge in a direction of the film thickness of the KNN piezoelectric film 4, to which a mapping from the EELS measurement was applied is not more than 0.8 eV, a desired good piezoelectric property can be obtained.

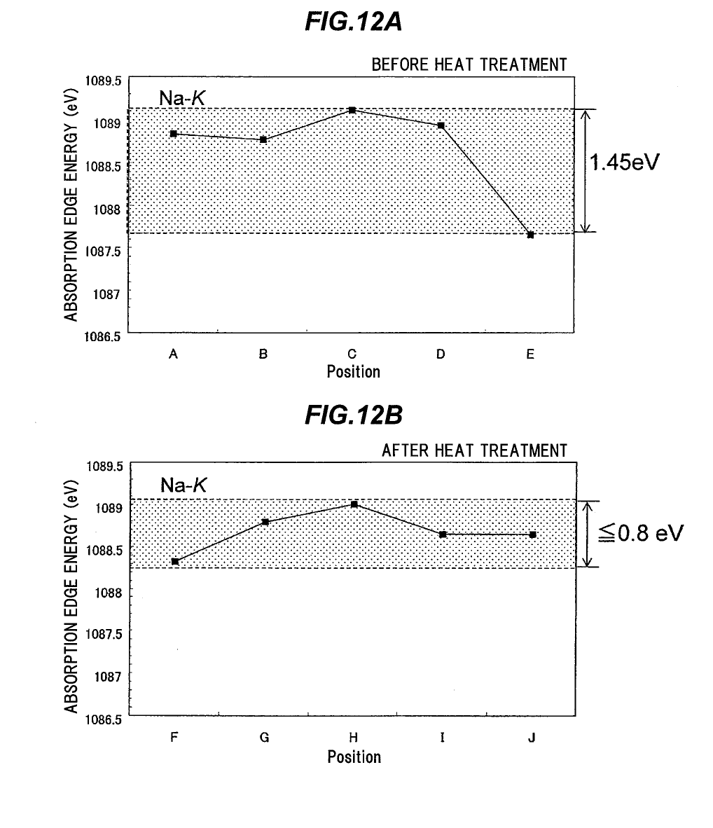

Next, FIGS. 12A, 12B show the change in an energy of the Na—K absorption edge in a direction of the film thickness of the KNN piezoelectric film 4 (in the position of the A to E and F to J shown in FIGS. 7A, 7B) based on the EELS spectrum of the Na—K absorption edge shown in FIGS. 9A, 9B. Here, FIG. 12A shows a case before the heat treatment (a case that the heat treatment is not carried out) and FIG. 12B shows a case after the heat treatment (a case that the heat treatment is carried out).

FIG. 12A of “before the heat treatment” shows that a difference of 1.2 to 1.5 eV (about 1.45 eV) is observed between the maximum value and the minimum value of an energy of the absorption edge of the Na—K absorption edge in the region from the vicinity of the surface of the KNN piezoelectric film 4 (the position of A) to the vicinity of the interface between the KNN piezoelectric film 4 and the Pt lower electrode layer 3 (the position of E). In particular, it is recognized that the energy of Na—K absorption edge in the vicinity of the interface between the Pt lower electrode layer 3 (the position of E) is dramatically decreased.

On the other hand, in FIG. 12B of “after the heat treatment”, an energy of the Na—K absorption edge in the vicinity of the interface between the KNN piezoelectric film 4 and the Pt lower electrode layer 3 (the position of J) is constant, and simultaneously a difference between the maximum value and the minimum value of an energy of the absorption edge of the Na—K absorption edge in the region from the vicinity of the surface of the KNN piezoelectric film 4 (the position of F) to the vicinity of the interface between the KNN piezoelectric film 4 and the Pt lower electrode layer 3 (the position of J) is decreased so as to be not more than 0.8 eV, in comparison with the difference of 1.2 to 1.5 eV (about 1.45 eV) before the heat treatment. It shows that the heat treatment was carried out, thereby the difference between the maximum value and the minimum value of an energy of the Na—K absorption edge in a direction of the film thickness of the KNN piezoelectric film 4 could be decreased to not more than 0.8 eV.

That is, it shows that by the heat treatment, in the vicinity of the interface between the KNN piezoelectric film 4 and the Pt lower electrode layer 3, oxygen was supplied to an oxygen deficiency site, an oxygen defect site or both sites of the oxygen deficiency and defect site around Na atom from the heat treatment atmosphere and an oxide on the substrate, thus the local structure around Na atom of the KNN piezoelectric film 4, in particular the binding state to oxygen was improved so as to be a uniform distribution over the region from the surface of the KNN piezoelectric film 4 to the interface between the Pt lower electrode layer (namely the distribution in a direction of the film thickness of the KNN piezoelectric film 4 was improved so as to be uniform).

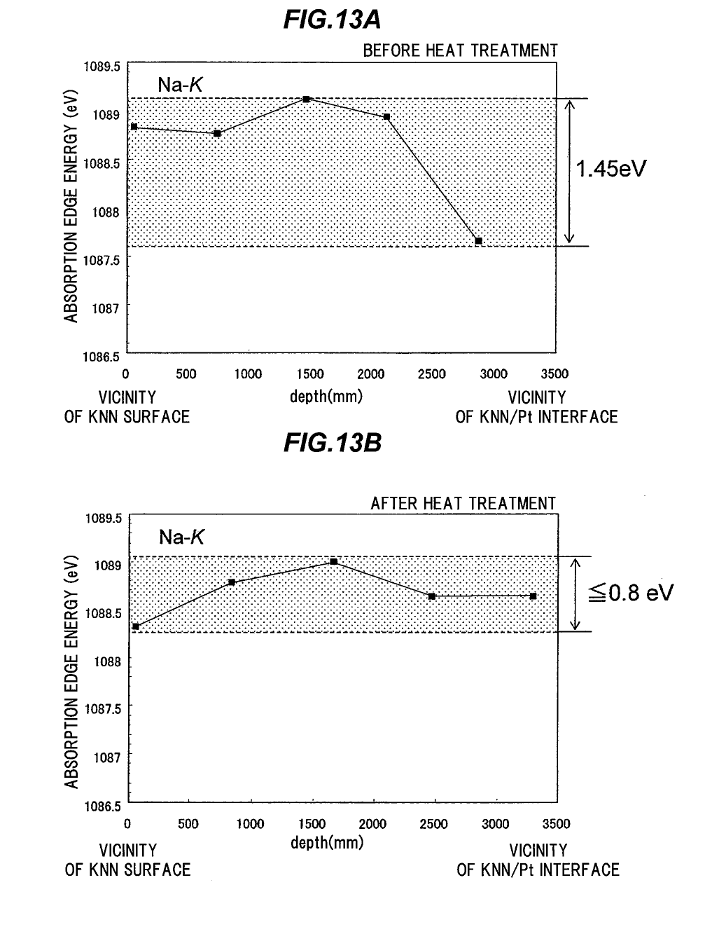

In addition, FIG. 13A shows the change in an energy of the Na—K absorption edge of the EELS relative to the film thickness of the KNN piezoelectric film 4 before the heat treatment. In the region from the surface of the KNN piezoelectric film 4 to about 2000 nm (about 2 μm) from the surface, the change in an energy of the Na—K absorption edge is small, and the energy value is positioned at about 1089 eV. It was recognized that the change in an energy of the Na—K absorption edge is drastically decreased in the region nearing the interface between the Pt lower electrode layer, the region being positioned lower by approximately 2 μm from the surface of the KNN piezoelectric film 4.

If the drastic change represents the decrease in the coordination number of oxygen that is the nearest neighbor atom around Na atom, it is expected that if the heat treatment is not carried out, the oxygen deficiency site around the Na atom of the KNN piezoelectric film 4 is configured such that the number of the oxygen deficiency is remarkably increased in the region nearing the interface between the Pt lower electrode layer, the region being positioned at a distance of approximately 2 to 3 μm from the interface.

Next, as a result of the heat treatment being applied to the KNN piezoelectric film 4, as can be seen from FIG. 13B, an energy of the Na—K absorption edge in a direction of the film thickness of the KNN piezoelectric film 4 becomes almost constant, and a difference between the maximum value and the minimum value of an energy of the absorption edge of the Na—K absorption edge in the region from the vicinity of the surface of the KNN piezoelectric film 4 (0 nm) to the vicinity of the interface between the KNN piezoelectric film 4 and the Pt lower electrode layer 3 (3500 nm) (namely in a direction of the film thickness of the KNN piezoelectric film 4) is decreased so as to be not more than 0.8 eV, in comparison with the difference between the maximum value and the minimum value of an energy of the absorption edge of the Na—K absorption edge in a direction of the film thickness of the KNN piezoelectric film 4 before the heat treatment. As a result of studying the piezoelectric property and the dielectric property comparatively, it was confirmed that if the difference between the maximum value and the minimum value of an energy of the Na—K absorption edge in a direction of the film thickness of the KNN piezoelectric film is controlled to be not more than 0.8 eV, a desired good piezoelectric property can be obtained.

With regard to the difference between the maximum value and the minimum value of an energy of the K-L (K-L₂, K-L₃) absorption edge and the Na—K absorption edge of the KNN piezoelectric film 4, the difference being obtained by the EELS measurement in the Measurement 3, Table 1 shows the piezoelectric constant, dielectric loss and relative permittivity in an application voltage of 4 V and 20 V to the controlled value. Further, a value representing the piezoelectric constant (property) is described by using a unit of −d₃₁ (pm/V). In the Example, control was carried out by the heat treatment in N₂O atmosphere at 800 degrees C. for 2 hours in order to specify the difference between the maximum value and the minimum value of an energy of each absorption edge by the EELS measurement so as to be a desired value. It has been proved by the Example that the difference between the maximum value and the minimum value of an energy of the absorption edge that allows the piezoelectric property of the KNN piezoelectric film 4 to be enhanced is not more than 0.8 eV in the case of the Na—K absorption edge and not more than 0.8 eV in the case of the K-L (K-L₂, K-L₃) absorption edge. Furthermore, if the differences between the maximum value and the minimum value of an energy of both of the Na—K absorption edge and the K-L (K-L₂, K-L₃) absorption edge are not more than 0.8 eV, it can be realized that various properties such as the piezoelectric constant, the dielectric property are further enhanced.

At the time, the piezoelectric constant −d₃₁ (pm/V) was enhanced from 48.0 to 64.9 in the applied voltage of 4 V, and from 80.5 to 98.3 in the applied voltage of 20 V. In addition, the dielectric tan δ was reduced from 0.298 to 0.087 to the extent of about not more than one-third, thus an effect that is directly linked to the device reliability such as decrease in leakage current was found out. Furthermore, it was also recognized that the

TABLE 1

| | | Piezoelectric constant | | | |
|---|---|---|---|---|---|
| | | −d₃₁ (pm/V) | | | |
| EELS absorption edge | | Applied | Applied | Dielectric | Relative |
| distribution width (eV) | | voltage | voltage | loss | permittivity |
| K-L₂, K-L₃ | Na—K | 4 V | 20 V | tan δ | εᵣ |
| 0.93 | 1.45 | 48.0 | 80.5 | 0.298 | 1056 |
| ≦0.8 | ≦0.8 | 64.9 | 98.3 | 0.087 | 1241 |

relative permittivity was enhanced, and it was proved that as described in Referential Literature 4, the invention contributed to enhancement of the piezoelectric constant that bears a directly proportionate relationship.
Referential Literature 4: Kiyoshi Okazaki, the fourth edition, Ceramic Dielectrics Engineering, (Gakukensya 1992).

As mentioned above, in a piezoelectric element configured such that at least a lower electrode layer; a piezoelectric film represented by a general formula of (NaₓK_{y}Li_{z})NbO₃ (0<x≦1, 0<y≦1, 0≦z≦0.2, x+y+z=1); and an upper electrode layer successively formed on the substrate, it is preferable that the piezoelectric film has a crystal structure of pseudo-cubic crystal, tetragonal crystal, orthorhombic crystal, monoclinic crystal or rhombohedral crystal, or has a state that at least two of the crystal structures coexist, and a difference between the maximum value and the minimum value of an energy of Na—K absorption edge measured by an electron energy loss spectroscopy or an X-ray-absorption fine-structure spectroscopy in a direction of the film thickness of the piezoelectric film is controlled in an energy range of not more than 0.8 eV, or a difference between the maximum value and the minimum value of an energy of K-L₂ absorption edge or/and K-L₃ absorption edge in a direction of the film thickness of the piezoelectric film is controlled in an energy range of not more than 0.8 eV.

Further, in the Example, the piezoelectric film was formed of the potassium sodium niobate, but even if the piezoelectric film is formed of the lithium potassium sodium niobate, or the piezoelectric film is formed of crystal or amorphous represented by a general formula of ABO₃, or the mixture of the crystal and the amorphous in at least a part thereof, similarly to the Example, it becomes possible to control a difference between the maximum value and the minimum value of an energy of the Na—K absorption edge, the K-L₂ absorption edge or/and the K-L₃ absorption edge in a direction of the film thickness of the piezoelectric film to be not more than 0.8 eV by the heat treatment after the formation of the piezoelectric film.

In addition, the energy measurement of the Na—K absorption edge, the K-L₂ absorption edge or/and the K-L₃ absorption edge of the KNN piezoelectric film was carried out by the EELS, but the energy measurement of the absorption edge can be also carried out by the XAFS spectroscopy.

As mentioned above, in a piezoelectric element, including a substrate and at least a lower electrode layer, a piezoelectric film and an upper electrode layer successively formed on the substrate, by the above-mentioned method, the local structure (the binding state) around the specific atom constituting the piezoelectric film is measured and indexed, and a heat treatment (at 800 degrees C. for 2 hours) is applied thereto after the formation of the piezoelectric film based on the results of the measurement and indexing, thereby it becomes possible to stably provide a piezoelectric element excellent in the piezoelectric property.

In addition, the piezoelectric element according to the invention is a piezoelectric element including a piezoelectric film comprised of lead-free materials, thus the piezoelectric element according to the invention is mounted therein, thereby a small size system device, for example, a micro electro mechanical system (MEMS) device, such as a small size motor, sensor actuator that is capable of reducing environment load and has a high performance can be provided.

Although the invention has been described with respect to the specific embodiments and Examples for complete and clear disclosure, the appended claims are not to be thus limited. In particular, it should be noted that all of the combinations of features as described in the embodiment and Examples are not always needed to solve the problem of the invention.

What is claimed is:

1. A piezoelectric element, comprising:
a substrate; and
a lower electrode layer, a piezoelectric film represented by a general formula of (NaₓK_{y}Li_{z})NbO₃ (0<x≦1, 0<y≦1, 0≦z≦0.2, x+_{y}+z=1) and an upper electrode layer formed on the substrate,
wherein the piezoelectric film has a crystal structure of pseudo-cubic crystal, tetragonal crystal, orthorhombic crystal, monoclinic crystal or rhombohedral crystal, or has a state that at least two of the crystal structures coexist, and
wherein a difference between the maximum value and the minimum value of an energy of Na—K absorption edge measured by an electron energy loss spectroscopy or an X-ray-absorption fine-structure spectroscopy in a direction of the film thickness of the piezoelectric film is not more than 0.8 eV.

2. The piezoelectric element according to claim 1, wherein a difference between the maximum value and the minimum value of an energy of K-L₂ absorption edge or/and an energy of K-L₃ absorption edge measured by an electron energy loss spectroscopy or an X-ray-absorption fine-structure spectroscopy in the film thickness direction of the piezoelectric film is not more than 0.8 eV.

3. The piezoelectric element, comprising:
a substrate; and
a lower electrode layer, a piezoelectric film and an upper electrode layer successively formed on the substrate,
wherein the piezoelectric film has a composition of crystal or amorphous represented by a general formula of ABO₃, or the mixture of the crystal and the amorphous in at least a part thereof, where A represents at least one element of Li, Na, K, Pb, La, Sr, Nd, Ba and Bi, B represents at least one element of Zr, Ti, Mn, Mg, Nb, Sn, Sb, Ta and In, and O represents oxygen, and
wherein a difference between the maximum value and the minimum value of an energy of the A atom absorption edge or/and an energy of the B atom absorption edge measured by an electron energy loss spectroscopy or an X-ray-absorption fine-structure spectroscopy in the film thickness direction of the piezoelectric film is not more than 0.8 eV.

4. The piezoelectric element according to claim 1, wherein the lower electrode layer comprises an electrode layer that is formed of a single layer or a multilayer structure, and is preferentially oriented in a direction perpendicular to the surface of the substrate in the crystal orientation.

5. The piezoelectric element according to claim 1, wherein the lower electrode layer comprise an electrode layer comprising Pt or an alloy containing Pt as a main component, or an electrode layer having a multilayer structure including a layer comprising Pt as a main component.

6. The piezoelectric element according to claim 1, wherein the lower electrode layer comprises an electrode layer comprising at least one element of Ru, Ir, Sn and In or the oxide of the elements.

7. The piezoelectric element according to claim 1, wherein the upper electrode layer comprises an electrode layer comprising Pt or an alloy containing Pt as a main component, or an electrode layer having a multilayer structure including a layer comprising Pt as a main component.

8. The piezoelectric element according to claim 1, wherein the upper electrode layer comprises an electrode layer comprising at least one element of Ru, Ir, Sn and In or the oxide of the elements.

9. The piezoelectric element according to claim 1, wherein the substrate comprises Si, MgO, ZnO, SrTiO₃, SrRuO₃, glass, quartz glass, GaAs, GaN, sapphire, Ge or stainless steel.

10. A piezoelectric device, comprising:
the piezoelectric element according to claim 1; and
a voltage applying device or a voltage detecting device connected between the lower electrode layer and the upper electrode layer of the piezoelectric element.

11. A method of manufacturing a piezoelectric element, wherein the piezoelectric element comprises a substrate and a lower electrode layer, a piezoelectric film represented by a general formula of (NaₓK_{y}Li_{z})NbO₃ (0<x≦1, 0<y≦1, 0≦z≦0.2, x+y+z=1) and an upper electrode layer formed on the substrate, comprising:
forming the piezoelectric film having a crystal structure of pseudo-cubic crystal, tetragonal crystal, orthorhombic crystal, monoclinic crystal or rhombohedral crystal, or having a state that at least two of the crystal structures coexist;
after the formation of the piezoelectric film, carrying out a heat treatment of the piezoelectric film in a vacuum, in an inert gas atmosphere, in O₂, in an O₂ and inert gas mixed gas, or in the air; and
controlling a difference between the maximum value and the minimum value of an energy of Na—K absorption edge measured by an electron energy loss spectroscopy or an X-ray-absorption fine-structure spectroscopy in the film thickness direction of the piezoelectric film to be not more than 0.8 eV.

12. The method according to claim 11, wherein a difference between the maximum value and the minimum value of an energy of K-L₂ absorption edge or/and an energy of K-L₃ absorption edge measured by an electron energy loss spectroscopy or an X-ray-absorption fine-structure spectroscopy in the film thickness direction of the piezoelectric film is controlled to be not more than 0.8 eV.

13. A method of manufacturing a piezoelectric element, wherein the piezoelectric element comprises a substrate and a lower electrode layer, a piezoelectric film and an upper electrode layer formed on the substrate, comprising:
forming the piezoelectric film having a composition of crystal or amorphous represented by a general formula of ABO₃, or the mixture of the crystal and the amorphous in at least a part thereof, where A represents at least one element of Li, Na, K, Pb, La, Sr, Nd, Ba and Bi, B represents at least one element of Zr, Ti, Mn, Mg, Nb, Sn, Sb, Ta and In, and O represents oxygen;
after the formation of the piezoelectric film, carrying out a heat treatment of the piezoelectric film in a vacuum, in an inert gas atmosphere, in O₂, in an O₂ and inert gas mixed gas, or in the air; and
controlling a difference between the maximum value and the minimum value of an energy of the A atom absorption edge or/and an energy of the B atom absorption edge measured by an electron energy-loss spectroscopy or an X-ray-absorption fine-structure spectroscopy in the film thickness direction of the piezoelectric film to be not more than 0.8 eV.
